(19) United States
(12) Patent Application Publication
(10) Pub. No.: US 2015/0255177 A1
(43) Pub. Date: Sep. 10, 2015

(54) SEMICONDUCTOR DEVICE AND MEMORY SYSTEM

(71) Applicant: Kabushiki Kaisha Toshiba, Minato-ku (JP)

(72) Inventor: Shuuji MATSUMOTO, Sagamihara-shi (JP)

(73) Assignee: Kabushiki Kaisha Toshiba, Minato-ku (JP)

(21) Appl. No.: 14/308,963

(22) Filed: Jun. 19, 2014

Related U.S. Application Data
(60) Provisional application No. 61/949,083, filed on Mar. 6, 2014.

(51) Int. Cl. G11C 29/52; G11C 16/32; G01K 1/02

(52) U.S. Cl. CPC G11C 29/52; G01K 1/02; G11C 16/32

(57) ABSTRACT

According to one embodiment, there is provided a semiconductor device including a temperature detection circuit, a first register, a second register, and a selector. The temperature detection circuit is configured to output a first level when the temperature exceeds the detection temperature from under the detection temperature, and output a second level when the temperature decreases under the open temperature from above the open temperature. The first register is configured to hold a value to set a first detection temperature into the temperature detection circuit. The second register is configured to hold a value to set a second detection temperature into the temperature detection circuit. The selector is configured to output either the value of the first register or the value of the second register based on an output level of the temperature detection circuit in order to set the detection temperature of the temperature detection circuit.

### CROSS-REFERENCE TO RELATED APPLICATIONS

This application is based upon and claims the benefit of priority from Provisional Application No. 61/949,083, filed on Mar. 6, 2014; the entire contents of which are incorporated herein by reference.

### FIELD

Embodiments described herein relate generally to a semiconductor device and a memory system.

### BACKGROUND

In recent years, a memory system provided with a NAND type flash memory has been sped up and downsized. The high speed has increased a heating amount of the system and the downsizing has deteriorated a heat dissipation characteristic of the system. Therefore, heat generation is becoming a problem. In order to solve this heat generation problem, it has been examined to provide a memory system with a temperature detecting function for the purpose of monitoring a temperature.

In a case of using a temperature sensor for detecting a temperature in detail, there are advantages that a temperature measurement range can be broadened and a temperature at the present moment can be known. However, at the same time, there are problems that the area of an analogue circuit is broadened and a designing period is prolonged. The memory system has been sophisticated and the price thereof has been reduced at the same time. Accordingly, considering the circuit area and the designing period, it is necessary to employ a temperature detection circuit with a simple analogue circuit.

### BRIEF DESCRIPTION OF THE DRAWINGS

FIG. 1 is a diagram illustrating a configuration of a semiconductor device according to a first embodiment;

FIG. 2 is a diagram illustrating a configuration of a temperature detection circuit according to the present embodiment;

FIG. 3 is a diagram illustrating a configuration of a memory system according to the present embodiment;

FIG. 4 is a diagram illustrating how the memory system according to the first embodiment controls a temperature;

FIG. 5 is a diagram illustrating a configuration of a semiconductor device according to a comparative example;

FIG. 6 is a diagram illustrating how a memory system according to the comparative example controls a temperature; and

FIG. 7 is a diagram illustrating a configuration of a semiconductor device according to a second embodiment.

### DETAILED DESCRIPTION

In general, according to one embodiment, there is provided a semiconductor device including a temperature detection circuit, a first register, a second register, and a selector. The temperature detection circuit has a detection temperature which is settable from outside and an open temperature lower than the detection temperature by a hysteresis temperature width depending on a circuit characteristic. The temperature detection circuit is configured to output a first level when the temperature exceeds the detection temperature from under the detection temperature, and output a second level when the temperature decreases under the open temperature from above the open temperature. The first register is configured to hold a value to set a first detection temperature into the temperature detection circuit. The second register is configured to hold a value to set a second detection temperature into the temperature detection circuit. The selector is configured to output either the value of the first register or the value of the second register based on an output level of the temperature detection circuit in order to set the detection temperature of the temperature detection circuit.

Exemplary embodiments of a semiconductor device will be explained below in detail with reference to the accompanying drawings. The present invention is not limited to the following embodiments.

### First Embodiment

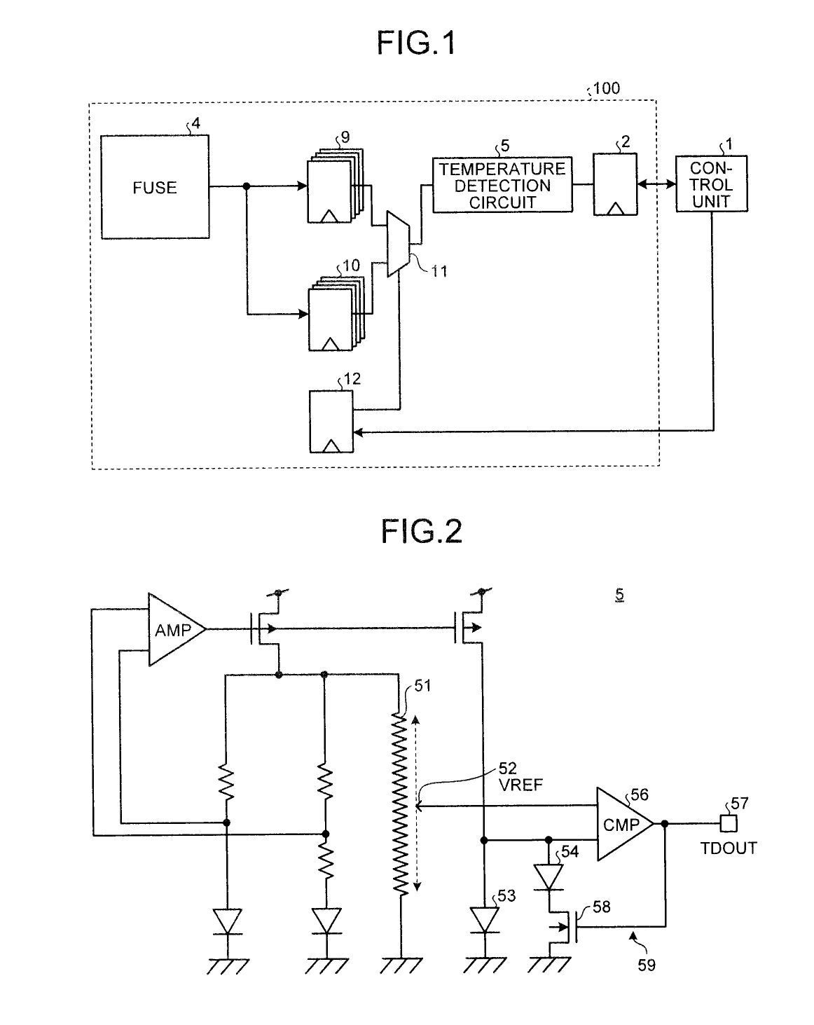

FIG. 1 is a diagram illustrating a configuration of a semiconductor device 100 according to the present embodiment. The semiconductor device 100 includes a fuse 4, a detection register 9 (first register), an open register 10 (second register), a selector 11 which outputs either a value of the detection register 9 or a value of the open register 10, a temperature detection circuit 5, a temperature detection register 2, and a selector control register 12. The selector control register 12 controls switching signals of the selector 11 and switches whether the selector 11 outputs the value of the detection register 9 or the value of the open register 10.

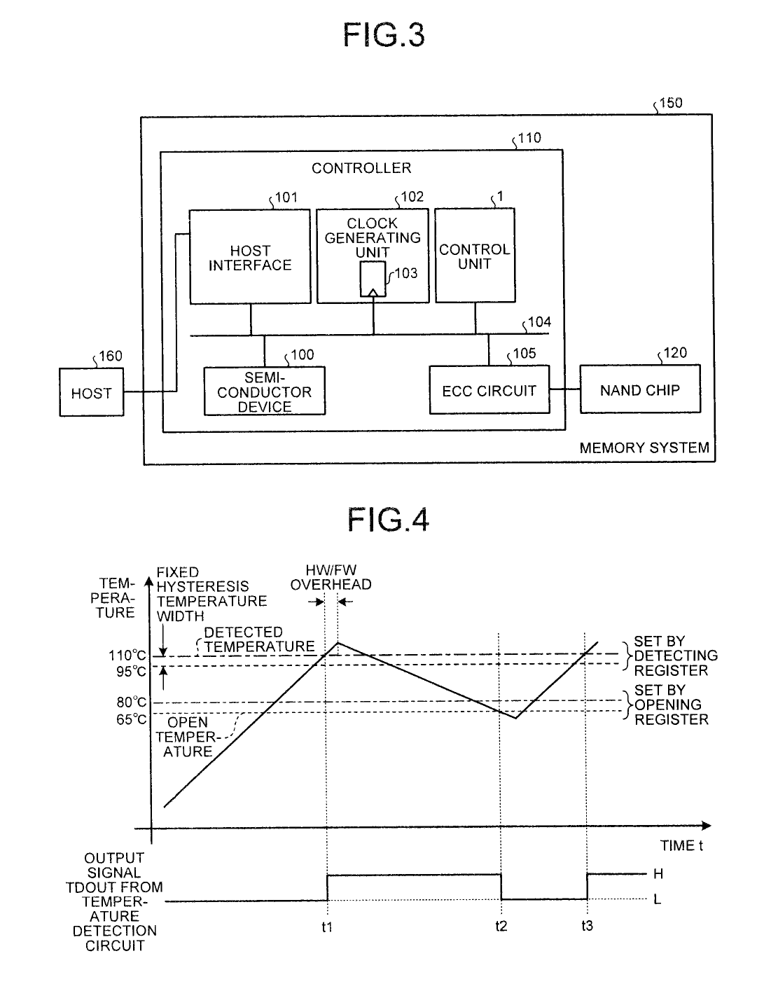

Further, the semiconductor device 100 and a control unit 1 such as a CPU which executes firmware are parts of, for example, a controller 110 of a memory system 150 illustrated in FIG. 3 (hereinafter described in detail). The control unit 1 controls an operation frequency of the semiconductor device 100 and a clock generating unit 102 based on a temperature detection result of the semiconductor device 100.

As an example of the temperature detection circuit 5, a typical analogue circuit for detecting a temperature is illustrated in FIG. 2. The temperature detection circuit 5 changes an output signal TDOUT57, that is, an output of a comparator 56, from “L” (second level) to “H” (first level) in a case where an ambient temperature exceeds a certain temperature (a temperature set in the temperature detection circuit 5). In the circuit illustrated in FIG. 2, a temperature setting signal VREF52 is a voltage which is set at an extracted position from a resistor 51. More specifically, a value of VREF52 can be changed, for example, between 0.5 V and 0.7 V in gradations of 5 bits by digital signals from outside.

The temperature detection circuit 5 is configured to change a set temperature, at which TDOUT57 changes from “L” to “H”, by varying the temperature setting signal VREF52. In this circuit, an open temperature at which TDOUT57 changes from “H” to “L” is a temperature lower than the set temperature by a certain temperature width. Changes of TDOUT57 from “L” to H″ and from “H” to “L” occur at different temperatures. In other words, the state of TDOUT57 (output characteristic of the temperature detection circuit 5) has a hysteresis regarding a temperature. Each resistance of diodes 53, 54 has temperature dependency. The diode is maintained to be enabled. If output level of the temperature detection circuit 5 becomes “H”, a transistor 58 receives “H” level signal at its gate via a feed-back line 59 and turns on to enable the diode 54. If output level of the temperature detection circuit 5 becomes “L”, the transistor 58 receives “L” level signal at its gate via the feed-back line 59 and turns off to disable the diode 54. With this operation, a temperature width which provides hysteresis (hysteresis temperature width) is determined by a resistance ratio between the diode 53 and the diode 54. Accordingly, the temperature width becomes a specific value determined by the temperature detection circuit 5.

In the semiconductor device 100, VREF52 is determined by an output value of the selector 11. That is, VREF52 is determined by either the value of the detection register 9 or the value of the open register 10. A detection temperature corresponding to VREF52 determined by the detection register 9 is set to be higher than a detection temperature corresponding to VREF52 determined by the open register 10. As described later, the detection temperature corresponding to VREF52 determined by the detection register 9 and the open temperature corresponding to VREF52 determined by the open register 10 are employed in the present embodiment. The detection temperature can be defined as a temperature at which output level of the temperature detection circuit 5 changes from “L” to “H”. The open temperature can be defined as a temperature at which output level of the temperature detection circuit 5 changes from “H” to “L”. The fuse 4 performs a trimming of the setting values of the detection register 9 and the open register 10 in order to improve temperature detection accuracy. That is, the fuse 4 calculates with firmware or hardware based on a trimming value, and adjusts and sets the value into the detection register 9 and the open register 10. With this operation, VREF52 can be switched by each value so that each value can freely change the set temperature.

Further, the state of TDOUT57 (output level of the temperature detection circuit 5) is set into the temperature detection register 2. The control unit 1 sets the value of the selector control register 12 based on the state of the temperature detection register 2 (output level of the temperature detection circuit 5 held by the temperature detection register 2). In such a case, the control unit 1 may periodically confirm the state of the temperature detection register 2 (polling), and may obtain the state of the temperature detection register 2. Alternatively, the control unit 1 may be interrupted by the temperature detection register 2 when the state of the temperature detection register 2 changes. As a result, VREF52 is set to either the value of the detection register 9 or that of the open register 10 based on the state of TDOUT57 of the temperature detection circuit 5.

FIG. 3 is a diagram illustrating a configuration of a memory system 150 according to the present embodiment. The memory system 150 is a memory card using, for example, a NAND-type flash memory. The memory system 150 is not restricted to a memory card which is removable from the host, but may be one that is installed fixedly in a much larger system such as e·MMC™. The memory system 150 includes a NAND chip 120 (non-volatile memory unit) and a controller 110 which controls the NAND chip 120 and carries out reading and writing based on an instruction from a host 160. The controller 110 includes a host interface 101 which receives commands from the host 160, a clock generating unit 102, the control unit 1, the semiconductor device 100, an ECC circuit 105 (error correction circuit) which carries out error correction processing in transmitting/receiving data to/from the NAND chip 120, and a bus 104. The host interface 101, the clock generating unit 102, the control unit 1, the semiconductor device 100, and the ECC circuit 105 are mutually connected through the bus 104. The host 160 is, for example, a smart phone. The semiconductor device 100 is configured as described above. The semiconductor device 100 and the control unit 1 operate as described above. The clock generating unit 102 controls clocks in the whole memory system 150 and can switch the memory system 150 between a low-speed mode (a first operation frequency mode with a low operation frequency) and a high-speed mode (a second operation frequency mode with an operation frequency higher than the first operation frequency) based on the value of the clock register 103.

How the memory system 150 according to the present embodiment controls a temperature is illustrated in FIG. 4. Herein, a temperature width which is generated in hysteresis in the temperature detection circuit 5 is, for example, 15° C. First, the control unit 1 sets the selector control register 12 so that the value of the detection register 9 is selected as the output value of the selector 11. Further, the control unit 1 sets the value of the clock register 103 to “1” (high-speed mode), and thereby sets the clock generating unit 102 to the high-speed mode. When the memory system 150 starts to operate in the high-speed mode, a temperature increases accordingly. When the temperature exceeds 110° C., that is, the detection temperature set by the detection register 9, TDOUT57 (output level of the temperature detection circuit 5) changes from “L” to “H”, and the state of the temperature detection register 2 becomes “H” (time t=t1).

When the control unit 1 detects that the state of the temperature detection register 2 has become “H”, the control unit 1 sets the value of the clock register 103 to “0” (low-speed mode), and thereby switches the clock generating unit 102 to the low-speed mode. At this time, the control unit 1 changes the value of the selector control register 12 and switches the selector 11 so that the value of the open register 10 is selected as the output value of the selector 11. Accordingly, 65° C. which is 15° C. lower than 80° C., that is, the detection temperature set by the open register 10 becomes an open temperature. It should be noted that, due to overhead for carrying out firmware or hardware, the time at which the high-speed mode is actually switched to the low-speed mode is a little later than the time t=t1 when the state of the temperature detection register 2 becomes “H”.

Then, when the temperature of the memory system 150 decreases to equal to or less than 65° C., that is, the open temperature set by the open register 10, TDOUT57 (output level of the temperature detection circuit 5) changes from “H” to “L” and the state of the temperature detection register 2 becomes “L” (time t=t2).

When the control unit 1 detects that the state of the temperature detection register 2 has become “L”, the control unit 1 sets the value of the clock register 103 to “1” (high-speed mode), and thereby switches the clock generating unit 102 to the high-speed mode. At this time, the control unit 1 changes the value of the selector control register 12 and switches the selector 11 so that the value of the detection register 9 is selected as the output value of the selector 11. Subsequently, the above-mentioned control is repeated.

It should be noted that, although the above-mentioned example describes a case where 95° C. is an open temperature corresponding to 110° C. which is the detection temperature set by the detection register 9 and where the detection temperature of 80° C. set by the open register 10 is lower than 95° C., this relation is not indispensable. There is no problem as long as the open temperature set by the open register 10 is freely set lower than the detection temperature set by the detection register 9, regardless of the temperature width specific to the temperature detection circuit 5. Accordingly, when the temperature width specific to the temperature detection circuit 5 widens and the difference between the detection temperature and the open temperature needs to become smaller than the temperature width, the detection temperature set by the open register 10 may be higher than the detection temperature set by the detection register 9, as long as the open temperature set by the open register 10 is lower than the detection temperature set by the detection register 9. Further, each detection temperature set by the detection register 9 and the open register 10 may be dynamically changed over time to achieve much finer temperature control.

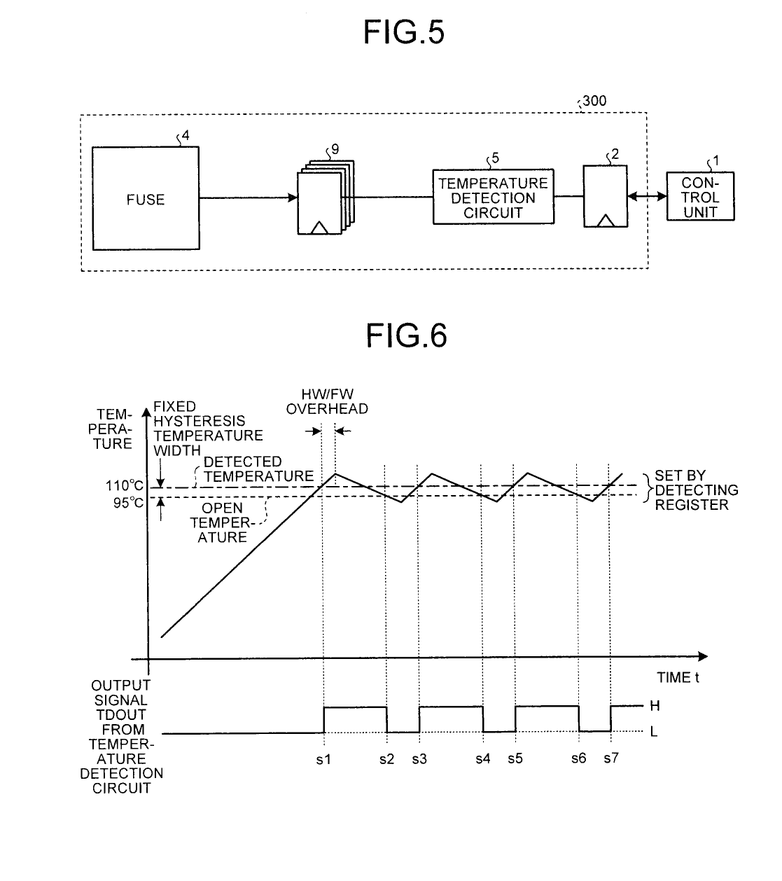

Next, a semiconductor device 300 according to a comparative example will be described. FIG. 5 is a diagram illustrating a configuration of the semiconductor device 300 according to the comparative example. The semiconductor device 300 includes a fuse 4, a detection register 9, a temperature detection circuit 5, and a temperature detection register 2. These components of the semiconductor device 300 are similar to those of the semiconductor device 100. A memory system employing the semiconductor device 300 according to the comparative example is one in which the semiconductor device 100 in FIG. 3 is replaced with the semiconductor device 300. The control unit 1 controls the clock generating unit 102 based on a temperature detection result of the semiconductor device 300.

How the memory system 150 employing the semiconductor device 300 instead of the semiconductor device 100 controls a temperature is illustrated in FIG. 6. Herein, a temperature width which is generated in hysteresis in the temperature detection circuit 5 is, for example, 15° C. First, the value of the clock register 103 is set to “1” (high-speed mode), and thereby the clock generating unit 102 is set to the high-speed mode. When the memory system 150 starts to operate in the high-speed mode, the temperature increases accordingly. When the temperature exceeds 110° C., that is, the detection temperature set by the detection register 9, TDOUT57 (output level of the temperature detection circuit 5) changes from “L” to “H”, and the state of the temperature detection register 2 becomes “H” (time t=s1).

When the control unit 1 detects that the state of the temperature detection register 2 has become “H”, the control unit 1 sets the value of the clock register 103 to “0” (low-speed mode), and thereby switches the clock generating unit 102 to the low-speed mode. When the temperature of the memory system 150 decreases to equal to or less than 95° C., that is, an open temperature 15° C. lower than the detection temperature set by the detection register 9, TDOUT57 (output level of the temperature detection circuit 5) changes from “H” to “L”, and the state of the temperature detection register 2 becomes “L” (time t=s2). When the control unit 1 detects that the state of the temperature detection register 2 has become “L”, the control unit 1 sets the value of the clock register 103 to “1” (high-speed mode), and switches the clock generating unit 102 to the high-speed mode. Subsequently, the above-mentioned control is repeated.

As described above, when the simplified temperature detection circuit 5 is employed, the difference between the detection temperature and the open temperature, that is, a temperature width which is generated in hysteresis (hysteresis temperature width), is a value fixed to the temperature detection circuit 5 (15° C. in the above description). In other words, although a setting of the detection temperature can be changed, the open temperature inevitably varies in conjunction with changes of the detection temperature. Accordingly, for example, in the memory system employing the semiconductor device 300 according to the comparative example, as ruled by this temperature difference, switching between the high-speed mode and the low-speed mode occurs frequently as illustrated in FIG. 6. In a stage of designing an analogue circuit, a value appropriate to the hysteresis temperature width cannot be determined, and the appropriate value is found after evaluating the whole memory system. Accordingly, it is difficult to set, into the temperature detection circuit 5, the hysteresis temperature width which is appropriate to the memory system.

By contrast, in the semiconductor device 100 according to the present embodiment, not only the detection temperature but also the open temperature can be set freely by disposing a plurality of registers, that is, a detection temperature setting register and an open temperature setting register. Further, the detection temperature and the open temperature can be set independently afterward. That is, the hysteresis temperature width can be freely changed regardless of the temperature width fixed to the temperature detection circuit 5. This makes it possible to perform temperature control appropriate to the memory system 150 including the semiconductor device 100. That is, the hysteresis temperature width can be set so as to switch between the high-speed mode and the low-speed mode at a frequency appropriate to the memory system 150.

### Second Embodiment

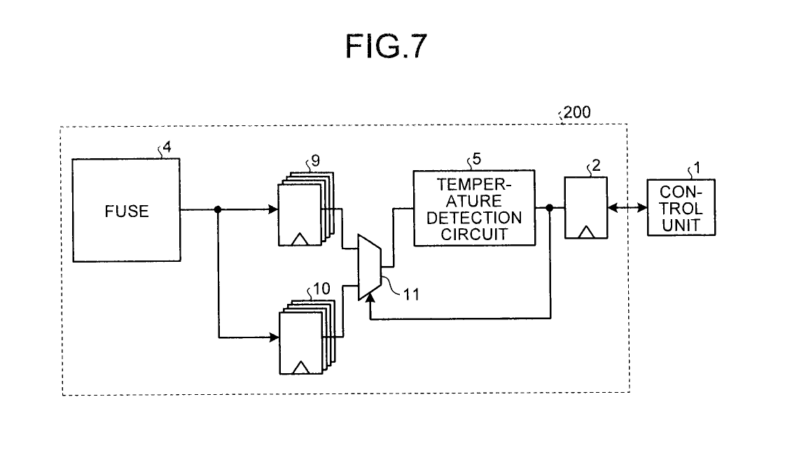

FIG. 7 is a diagram illustrating a configuration of a semiconductor device 200 according to the present embodiment. The semiconductor device 200 includes a fuse 4, a detection register 9, an open register 10, a selector 11 which outputs either the value of the detection register 9 or the value of the open register 10, a temperature detection circuit 5, and a temperature detection register 2. These components of the semiconductor device 200 are similar to those of the semiconductor device 100 according to the first embodiment. However, the semiconductor device 200 is different from the semiconductor device 100 in that the selector 11 is controlled by the state of TDOUT57 (output level of the temperature detection circuit 5) without involving the control unit 1. In other words, when TDOUT57 is “L” at first, in changing TDOUT57 from “L” to “H”, the selector 11 is immediately switched so that the value of the open register 10 is selected as the output value of the selector 11. By contrast, in changing TDOUT57 from “H” to “L”, the selector 11 is immediately switched so that the value of the detection register 9 is selected as the output value of the selector 11.

How the memory system 150 employing the semiconductor device 200 instead of the semiconductor device 100 controls a temperature is illustrated in FIG. 4 as in the first embodiment. This makes it possible to perform temperature control appropriate to the memory system 150 including the semiconductor device 200. Further, according to the semiconductor device 200 of the present embodiment, in the memory system 150 employing the same, it is possible to reduce switching overhead between the low-speed mode and the high-speed mode, because the control unit 1 does not control the selector 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a temperature detection circuit having a detection temperature which is settable from outside and an open temperature lower than the detection temperature by a hysteresis temperature width depending on a circuit characteristic, the temperature detection circuit being configured to output a first level when the temperature exceeds the detection temperature from under the detection temperature, and output a second level when the temperature decreases under the open temperature from above the open temperature;
a first register configured to hold a value to set a first detection temperature into the temperature detection circuit;
a second register configured to hold a value to set a second detection temperature into the temperature detection circuit; and
a selector configured to output either the value of the first register or the value of the second register based on an output level of the temperature detection circuit in order to set the detection temperature of the temperature detection circuit.

2. The semiconductor device according to claim 1, further comprising a temperature detection register configured to hold the output level of the temperature detection circuit,
wherein the selector outputs either the value of the first register or the value of the second register based on the level held by the temperature detection register in order to set the detection temperature of the temperature detection circuit.

3. The semiconductor device according to claim 1, further comprising a selector control register connected to the selector and configured to hold a value based on the output level of the temperature detection circuit configured to determine whether the selector outputs the value of the first register or the value of the second register.

4. The semiconductor device according to claim 2, further comprising a selector control register connected to the selector and configured to hold a value based on the level held by the temperature detection register configured to determine whether the selector outputs the value of the first register or the value of the second register.

5. The semiconductor device according to claim 1, wherein
the open temperature lower than the second detection temperature by the hysteresis temperature width is lower than the first detection temperature.

6. The semiconductor device according to claim 4, wherein
the open temperature lower than the second detection temperature by the hysteresis temperature width is lower than the first detection temperature.

7. The semiconductor device according to claim 1, further comprising a fuse configured to adjust the value held in the first register and the value held in the second register.

8. The semiconductor device according to claim 1, wherein
the hysteresis temperature width is determined by a resistance ratio of two diodes included in the temperature detection circuit.

9. A memory system comprising:
a temperature detection circuit having a detection temperature which is settable from outside and an open temperature lower than the detection temperature by a hysteresis temperature width depending on a circuit characteristic, the temperature detection circuit being configured to output a first level when the temperature exceeds the detection temperature from under the detection temperature, and output a second level when the temperature decreases under the open temperature from above the open temperature;
a first register configured to hold a value to set a first detection temperature into the temperature detection circuit;
a second register configured to hold a value to set a second detection temperature into the temperature detection circuit;
a selector configured to output either the value of the first register or the value of the second register based on an output level of the temperature detection circuit in order to set the detection temperature of the temperature detection circuit;
a clock generating unit configured to control a clock;
a non-volatile memory unit; and
a control unit configured to control an operation frequency of the clock generating unit based on the output level of the temperature detection circuit.

10. The memory system according to claim 9, further comprising a temperature detection register configured to hold the output level of the temperature detection circuit,
wherein the selector outputs either the value of the first register or the value of the second register based on the level held by the temperature detection register in order to set the detection temperature of the temperature detection circuit.

11. The memory system according to claim 9, further comprising a selector control register connected to the selector and configured to hold a value based on the output level of the temperature detection circuit configured to determine whether the selector outputs the value of the first register or the value of the second register.

12. The memory system according to claim 10, further comprising a selector control register connected to the selector and configured to hold a value based on the level held by the temperature detection register configured to determine whether the selector outputs the value of the first register or the value of the second register.

13. The memory system according to claim 9, further comprising an error correction circuit configured to carry out error correction processing in transmitting and receiving data to/from the non-volatile memory unit.

14. The memory system according to claim 12, further comprising an error correction circuit configured to carry out error correction processing in transmitting and receiving data to/from the non-volatile memory unit.

15. The memory system according to claim 9, wherein
the open temperature lower than the second detection temperature by the hysteresis temperature width is lower than the first detection temperature.

16. The memory system according to claim 12, wherein
the open temperature lower than the second detection temperature by the hysteresis temperature width is lower than the first detection temperature.

17. The memory system according to claim 9, wherein
the control unit controls the clock generating unit to have a first operation frequency when the temperature detection circuit outputs the first level, and controls the clock generating unit to have a second operation frequency which is higher than the first operation frequency when the temperature detection circuit outputs the second level.

18. The memory system according to claim 12, wherein
the control unit controls the clock generating unit to have a first operation frequency when the temperature detection circuit outputs the first level, and controls the clock generating unit to have a second operation frequency which is higher than the first operation frequency when the temperature detection circuit outputs the second level.

19. The memory system according to claim 9, further comprising a fuse configured to adjust the value held in the first register and the value held in the second register.

20. The memory system according to claim 9, wherein
the hysteresis temperature width is determined by a resistance ratio of two diodes included in the temperature detection circuit.
